(19) United States
(12) Patent Application Publication
(10) Pub. No.: US 2026/0065955 A1
(43) Pub. Date: Mar. 5, 2026

(54) WIRING STRUCTURE OF MEMORY AND MEMORY

(71) Applicant: CXMT Corporation, Hefei (CN)

(72) Inventor: Chao Wang, Hefei (CN)

(73) Assignee: CXMT Corporation, Hefei (CN)

(21) Appl. No.: 19/381,445

(22) Filed: Nov. 6, 2025

Related U.S. Application Data
(63) Continuation of application No. PCT/CN2024/103014, filed on Jul. 2, 2024.

(30) Foreign Application Priority Data
Dec. 25, 2023 (CN) 202311785507.8

(51) Int. Cl. G11C 5/06; G11C 11/408

(52) U.S. Cl. CPC G11C 5/063; G11C 11/4087

(57) ABSTRACT

The present disclosure provides a wiring structure of a memory and a memory. The wiring structure includes: a first operation unit configured to receive an initial control signal and a first enable signal and generate a first control signal; a second operation unit configured to receive the initial control signal and a second enable signal and generate a second control signal; a signal processing unit configured to receive and process the initial control signal, the first enable signal, and the second enable signal separately; and a first transmission unit, where the first transmission unit and the signal processing unit are jointly configured to: transmit the initial control signal to the first operation unit and the second operation unit separately, and ensure that a difference between delays of the initial control signals received by the first operation unit and the second operation unit separately is less than a preset threshold.

### CROSS-REFERENCE TO RELATED APPLICATIONS

The present disclosure is a US continuation application of International Application No. PCT/CN2024/103014, filed on July 02, 2024, which is based on and claims priority to Chinese Patent Application No. 202311785507.8, filed with China National Intellectual Property Administration on December 25, 2023 and entitled "WIRING STRUCTURE OF MEMORY AND MEMORY", the content of which is incorporated herein by reference in its entirety.

### TECHNICAL FIELD

Embodiments of the present disclosure relate to the technical field of semiconductors, and in particular, to a wiring structure of a memory and a memory.

### BACKGROUND

In general, a semiconductor device may include a memory array region and a peripheral region, and a lot of signal lines and power supply lines can be arranged at upper parts of the memory array region and the peripheral region. The peripheral region includes a plurality of signal processing regions such as a column decoding region and a row decoding region. With the increasing demand for portability, computational capability, memory capacity, and energy efficiency of modern electronic products, the area for laying out the row decoding region is desired to be minimized in DRAM chip design.

However, with a smaller area for laying out the row decoding region, the space above the row decoding region for wiring is further reduced, resulting in insufficient space resources for laying out some wiring. In view of this, with the precondition of ensuring that the transmission performance of the wiring is not affected, how to reduce the space for laying out the wiring becomes an urgent problem to be solved.

### SUMMARY

According to some embodiments of the present disclosure, in one aspect, the embodiments of the present disclosure provide a wiring structure of a memory. The wiring structure includes: a first column decoding region and a second column decoding region that are spaced apart along a first direction, where the first column decoding region is provided with a first operation unit configured to receive an initial control signal and a first enable signal and generate a first control signal; and the second column decoding region is provided with a second operation unit configured to receive the initial control signal and a second enable signal and generate a second control signal; a row decoding region, located between the first column decoding region and the second column decoding region; a signal processing unit, located on a side that is near the second column decoding region and far away from the first column decoding region and configured to: receive the initial control signal, the first enable signal, and the second enable signal, and process the initial control signal, the first enable signal, and the second enable signal separately; and a first transmission unit, where the first transmission unit and the signal processing unit are jointly configured to: transmit the initial control signal to the first operation unit and the second operation unit separately, and ensure that a difference between a first delay of the initial control signal received by the first operation unit and a second delay of the initial control signal received by the second operation unit is less than a preset threshold.

According to some embodiments of the present disclosure, in another aspect, the embodiments of the present disclosure further provide a memory. The memory includes the wiring structure according to any one of the foregoing embodiments.

### BRIEF DESCRIPTION OF DRAWINGS

One or more embodiments are illustrated by figures in corresponding drawings, and the exemplary illustration is not to be construed as limiting the embodiments. Elements with the same reference numeral represent similar elements. Unless otherwise specified, the figures in the drawings do not constitute limitations in terms of scale. For clearer illustration of the technical solutions in the embodiments of the present disclosure or a conventional technology, the drawings required to be used in the embodiments are briefly described below. It is clear that the drawings in the description below are only some embodiments of the present disclosure, and for those of ordinary skill in the art, other drawings can be obtained based on these drawings without creative efforts.

FIG. 1 is a schematic partial top view of a wiring structure;

FIG. 2 is a functional block diagram of a wiring structure according to an embodiment of the present disclosure;

FIG. 3 is a schematic partial top view of a wiring structure according to an embodiment of the present disclosure;

FIG. 4 is a combined functional block diagram of a signal processing unit, a first transmission unit, a first operation unit, and a second operation unit in a wiring structure according to an embodiment of the present disclosure;

FIG. 5 is another schematic top view of a wiring structure according to an embodiment of the present disclosure;

FIG. 6 is still another schematic top view of a wiring structure according to an embodiment of the present disclosure;

FIG. 7 is yet another schematic top view of a wiring structure according to an embodiment of the present disclosure;

FIG. 8 is a schematic top view of a first transmission unit in the wiring structure shown in FIG. 7;

FIG. 9a is a schematic top view of a first transmission path formed by a main path and a first branch in the first transmission unit shown in FIG. 8;

FIG. 9b is a schematic top view of a second transmission path formed by a main path and a second branch in the first transmission unit shown in FIG. 8;

FIG. 10 is a schematic top view of a wiring structure further provided with shield lines based on the structure shown in FIG. 7;

FIG. 11 is yet another schematic top view of a wiring structure according to an embodiment of the present disclosure;

FIG. 12 is yet another schematic top view of a wiring structure according to an embodiment of the present disclosure;

FIG. 13 is yet another schematic top view of a wiring structure according to an embodiment of the present disclosure;

FIG. 14 is a schematic combined top view of a first transmission unit, a first memory array region, a row decoding region, and a second memory array region in the wiring structure shown in FIG. 13;

FIG. 15 is a schematic top view of a first transmission unit in the wiring structure shown in FIG. 12;

FIG. 16 is a schematic top view of a wiring structure further provided with shield lines based on the structure shown in FIG. 13;

FIG. 17 is another schematic top view of a first transmission unit in a wiring structure according to an embodiment of the present disclosure; and

FIG. 18 is a schematic structural diagram of a memory according to an embodiment of the present disclosure.

### DESCRIPTION OF EMBODIMENTS

As can be learned from the background, with the precondition of ensuring high transmission performance of the wiring, the space for laying out the wiring needs to be reduced.

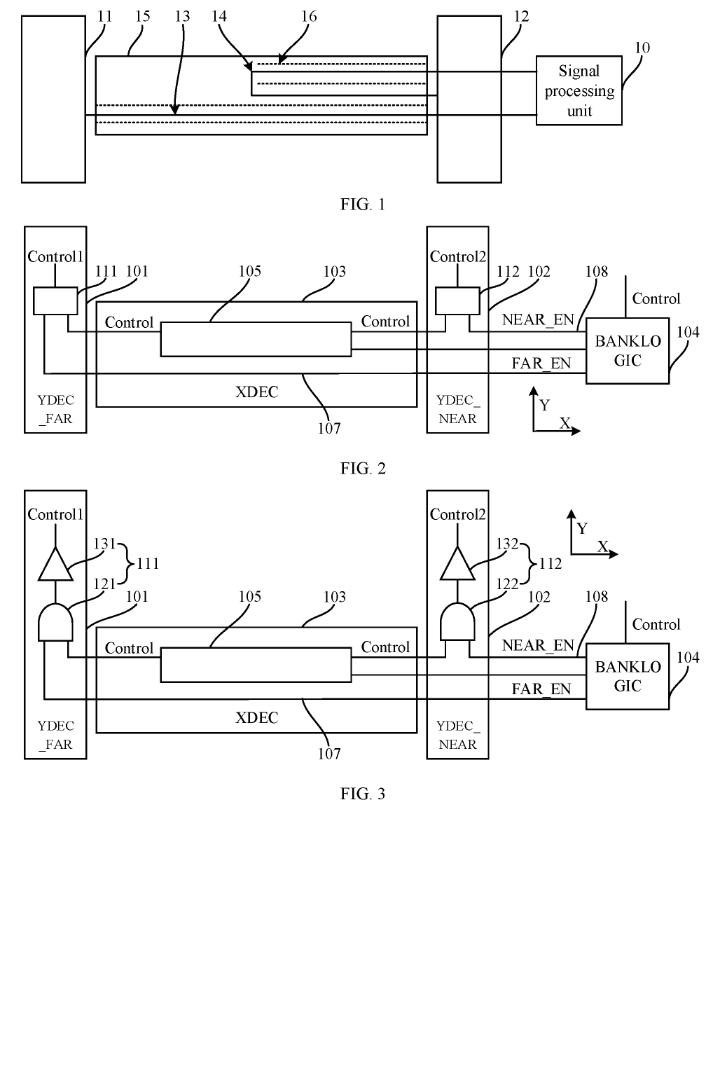

Based on findings through analysis, referring to FIG. 1, FIG. 1 is a schematic partial top view of a wiring structure. In a semiconductor device, a signal processing unit 10 receives an initial signal and transmits the initial signal that has been processed to a first column decoding region 11 and a second column decoding region 12 separately. Based on this, it is necessary to design a first wire 13 for transmitting the signal output by the signal processing unit 10 to the first column decoding region 11, and a second wire 14 for transmitting the signal output by the signal processing unit 10 to the second column decoding region 12. The space for laying out the first wire 13 and the second wire 14 is a wiring region 15 shown in FIG. 1.

In some cases, after receiving the initial signal, the signal processing unit 10 processes the initial signal to generate a first control signal for controlling subsequent operations to be performed in the first column decoding region 11 and a second control signal for controlling subsequent operations to be performed in the second column decoding region 12, and provides the generated first control signal for the first column decoding region 11 via the first wire 13 and the generated second control signal for the second column decoding region 12 via the second wire 14. The first column decoding region 11 and the second column decoding region 12 separately perform the subsequent operations based on the received control signals. Further, based on different initial signals, the control signals provided by the signal processing unit 10 for the first column decoding region 11 and the second column decoding region 12 are different. Based on this, there is a high requirement on the transmission performance of the first wire 13 and the second wire 14.

In one aspect, the time for the first control signal output by the signal processing unit 10 to be transmitted to the first column decoding region 11 via the first wire 13 is denoted as a first time, and the time for the second control signal output by the signal processing unit 10 to be transmitted to the second column decoding region 12 via the second wire 14 is denoted as a second time. Since the signal processing unit 10 is at different distances from the first column decoding region 11 and the second column decoding region 12, at least one of the first wire 13 and the second wire 14 needs to be rerouted, to reduce the difference between the first time and the second time. FIG. 1 shows an example in which the signal processing unit 10 is closer to the second column decoding region 12 and the second wire 14 is rerouted. It can be understood that, rerouting the second wire 14 can increase the area for laying out the second wire 14 in the wiring region 15.

In another aspect, the first column decoding region 11 and the second column decoding region 12 need to receive the control signals output by the signal processing unit 10 accurately for the subsequent operations. Based on this, the first wire 13 and the second wire 14 need to have high transmission accuracy, that is, the distortion rates during the transmission of the control signals through the first wire 13 and the second wire 14 need to be reduced. Therefore, a shield line 16 needs to be provided between any two adjacent wires, to reduce mutual electrical interference between the adjacent wires. The wires described herein include the first wire 13 and the second wire 14. It can be understood that, adding the shield line 16 can increase the layout space required for the wiring region 15.

Referring to FIG. 1, one shield line 16 needs to be provided between the first wire 13 and the second wire 14; since the second wire 14 itself is rerouted, at least one shield line 16 needs to be provided inside the second wire 14; and further, one shield line 16 needs to be provided between the first wire 13 and another external wire, and one shield line 16 needs to be provided between the second wire 14 and another external wire. Therefore, to reduce the distortion rates during the transmission of the control signals through the first wire 13 and the second wire 14, at least four shield lines 16 need to be provided for one first wire 13 and one second wire 14. Therefore, the shield lines 16 of a larger quantity than that of the first wire 13 and the second wire 14 further increase the layout space for the wiring region 15.

It should be noted that, in FIG. 1, the first wire 13 and the second wire 14 are illustrated by solid lines, and the shield lines 16 are indicated by broken lines.

In still another aspect, there are a plurality of types of initial signals to be received by the signal processing unit 10, and any one type of the initial signals processed by the signal processing unit 10 turns into two output signals, that is, the first control signal and the second control signal. As there are a plurality of types, for example, N types, of initial signals to be received by the signal processing unit 10, where N is a positive integer, N first wires 13 and N second wires 14 need to be provided in the wiring region 15. Further, one first wire 13 and one second wire 14 are used as one group of signal transmission lines, and with the shield lines 16, even if one shield line 16 can be shared by adjacent groups of signal transmission lines, the total quantity of wires to be provided in the wiring region 15 needs to be at least (6N+1) to transmit 2N output signals generated based on the N types of initial signals. The wires herein include the first wire 13, the second wire 14, and the shield line 16.

As can be learned from the foregoing analysis, to ensure high transmission performance of the first wire 13 and the second wire 14, a large quantity of tracks need to be laid out in the wiring region 15, and a large layout space is required for the wiring region 15, which is not favorable for the scaling of semiconductor devices. It should be noted that, one wire may occupy at least one track.

Therefore, with the precondition of ensuring that the transmission performance of the wiring is not affected, how to reduce the space for laying out the wiring becomes an urgent problem to be solved.

The embodiments of the present disclosure provide a wiring structure of a memory and a memory. In the wiring structure, in one aspect, a first transmission unit and a signal processing unit can work jointly to ensure that the difference between a first delay of an initial control signal received by a first operation unit and a second delay of the initial control signal received by a second operation unit is less than a preset threshold. In other words, the difference between the times for the signal output by the signal processing unit to be transmitted to the first column decoding region and to the second column decoding region via the first transmission unit is controlled to be less than the preset threshold, such that the transmission performance of the wiring structure is improved. In another aspect, as the first operation unit is provided within the first column decoding region, and the second operation unit is provided within the second column decoding region, not only can the signal processing unit primarily process the received initial control signal, but also the initial control signal can be received and re-processed by the first operation unit in the first column decoding region, so as to finally generate a first control signal for driving subsequent operations to be performed in the first column decoding region. Further, the initial control signal can be received and re-processed by the second operation unit in the second column decoding region, so as to finally generate a second control signal for driving subsequent operations to be performed in the second column decoding region. Therefore, the first transmission unit only needs to transmit one type of signals, that is, transmit the initial control signal that has been received and processed by the signal processing unit to the first operation unit and the second operation unit, to help reduce the space for laying out the first transmission unit, and then reduce the space for laying out the wiring structure.

The embodiments of the present disclosure will be described in detail below with reference to the drawings. However, those of ordinary skill in the art can understand that in the embodiments of the present disclosure, numerous technical details are set forth in order to enable readers to better understand the embodiments of the present disclosure. However, the technical solutions claimed by the embodiments of the present disclosure can also be implemented even without these technical details and the various changes and modifications based on the following embodiments.

An embodiment of the present disclosure provides a wiring structure of a memory. The wiring structure of a memory according to this embodiment of the present disclosure is described in detail below with reference to the drawings.

FIG. 2 is a functional block diagram of a wiring structure according to an embodiment of the present disclosure.

Referring to FIG. 2, the wiring structure of a memory includes: a first column decoding region 101 and a second column decoding region 102 that are spaced apart along a first direction X, where the first column decoding region 101 is provided with a first operation unit 111 configured to receive an initial control signal Control and a first enable signal FAR_EN and generate a first control signal Control1; and the second column decoding region 102 is provided with a second operation unit 112 configured to receive the initial control signal Control and a second enable signal NEAR_EN and generate a second control signal Control2; a row decoding region 103, located between the first column decoding region 101 and the second column decoding region 102; a signal processing unit 104, located on a side that is near the second column decoding region 102 and far away from the first column decoding region 101 and configured to: receive the initial control signal Control, the first enable signal FAR_EN, and the second enable signal NEAR_EN, and process the initial control signal Control, the first enable signal FAR_EN, and the second enable signal NEAR_EN separately; and a first transmission unit 105, where the first transmission unit 105 and the signal processing unit 104 are jointly configured to: transmit the initial control signal Control to the first operation unit 111 and the second operation unit 112 separately, and ensure that a difference between a first delay of the initial control signal Control received by the first operation unit 111 and a second delay of the initial control signal Control received by the second operation unit 112 is less than a preset threshold.

It should be noted that, the first column decoding region 101, the second column decoding region 102, and the row decoding region 103 are division of different regions of the wiring structure, and the main functions implemented by each of the regions are different. By dividing the wiring structure into different regions, position relationships between different electrical components are made clear. The first column decoding region 101 includes, but is not limited to, the first operation unit 111, and the second column decoding region 102 includes, but is not limited to, the second operation unit 112.

It can be understood that, the signal processing unit 104 and the first transmission unit 105 work jointly to transmit the initial control signal Control received by the signal processing unit 104 to the first operation unit 111 and the second operation unit 112 separately. The transmission performance of the wiring structure can be improved through the transmission. Detailed description is provided below. The new signal processing unit 104 and the new first transmission unit 105 are designed, and the signal processing unit 104 and the first transmission unit 105 can work jointly to ensure that the difference between the first delay of the initial control signal Control received by the first operation unit 111 and the second delay of the initial control signal Control received by the second operation unit 112 is less than the preset threshold. In other words, the signal output by the signal processing unit 104 is separately transmitted to the first operation unit 111 and the second operation unit 112 via the first transmission unit 105, and the difference between the moments at which the first operation unit 111 and the second operation unit 112 receive the initial control signal Control is controlled to be less than the preset threshold with the signal transmission of the first transmission unit 105, that is, the difference between the times for the signal output by the signal processing unit 104 to be transmitted to the first column decoding region 101 and to the second column decoding region 102 via the first transmission unit 105 is controlled to be less than the preset threshold, such that the transmission performance of the wiring structure is improved.

In another aspect, as the first operation unit 111 is provided within the first column decoding region 101, and the second operation unit 112 is provided within the second column decoding region 102, not only can the signal processing unit 104 primarily process the received initial control signal Control, but also the initial control signal Control that has been processed by the signal processing unit 104 and the first transmission unit 105 can be re-processed by the first operation unit 111 in the first column decoding region 101, so as to finally generate the first control signal Control1 for driving subsequent operations to be performed in the first column decoding region 101. Further, the initial control signal Control that has been processed by the signal processing unit 104 and the first transmission unit 105 can be re-processed by the second operation unit 112 in the second column decoding region 102, so as to finally generate the second control signal Control2 for driving subsequent operations to be performed in the second column decoding region 102.

In other words, in the newly designed wiring structure, rather than only relying on the signal processing unit 104 to process the initial control signal Control to generate the control signals for driving the subsequent operations to be performed in the first column decoding region 101 and the second column decoding region 102, the first operation unit 111 and the second operation unit 112 capable of processing the initial control signal Control are further designed in the first column decoding region 101 and the second column decoding region 102 respectively, such that the first control signal Control1 for driving the subsequent operations to be performed in the first column decoding region 101 is generated in the first column decoding region 101, and the second control signal Control2 for driving the subsequent operations to be performed in the second column decoding region 102 is generated in the second column decoding region 102. Therefore, the first transmission unit 105 only needs to transmit one type of signals, that is, the first transmission unit 105 transmits the initial control signal Control that has been received and processed by the signal processing unit 104 to the first operation unit 111 and the second operation unit 112, to help reduce the space for laying out the first transmission unit 105, and then reduce the space for laying out the wiring structure.

Further, the signal processing unit 104 only needs to primarily process the received initial control signal Control, and does not need to generate the first control signal Control1 in the signal processing unit 104 based on the initial control signal Control and the first enable signal FAR_EN, or generate the second control signal Control2 in the signal processing unit 104 based on the initial control signal Control and the second enable signal NEAR_EN. This is beneficial to simplifying the logic of processing the initial control signal Control by the signal processing unit 104, and thus to reducing the complexity of the logic circuit in the signal processing unit 104, so as to reduce the space for laying out the signal processing unit 104 and further reduce the space for laying out the wiring structure.

It should be noted that, in FIG. 2, the first column decoding region 101 is denoted as YDEC_FAR, the second column decoding region 102 is denoted as YDEC_NEAR, the row decoding region 103 is denoted as XDEC, and the signal processing unit 104 is denoted as BANKLOGIC. In addition, to illustrate a transmission path of the initial control signal Control through the signal processing unit 104, the first transmission unit 105, the first operation unit 111, and the second operation unit 112, the first transmission unit 105 is shown in FIG. 2 merely as a simple functional block diagram.

In some cases, since the row decoding region 103 is located between the first column decoding region 101 and the second column decoding region 102, and the signal processing unit 104 is located on the side near the second column decoding region 102 and far away from the first column decoding region 101, that is, the signal processing unit 104 is located at the periphery of a region formed by the first column decoding region 101, the second column decoding region 102, and the row decoding region 103, when the signal output by the signal processing unit 104 is transmitted to the first column decoding region 101 and the second column decoding region 102 separately via the first transmission unit 105, the transmission path of the signal run through the row decoding region 103 along the first direction X.

The wiring structure is described in further detail below with reference to the drawings.

In some embodiments, the difference between the first delay of the initial control signal Control received by the first operation unit 111 and the second delay of the initial control signal Control received by the second operation unit 112 is less than the preset threshold, and the preset threshold ranges from 0 ps to 30 ps.

In practical application, the first column decoding region 101 further includes a first column decoder (not shown in the figure), and the first column decoder performs subsequent operations based on the first control signal Control1 generated by the first operation unit 111; and the second column decoding region 102 further includes a second column decoder (not shown in the figure), and the second column decoder performs subsequent operations based on the second control signal Control2 generated by the second operation unit 112. Further, a smaller difference between the moment at which the first control signal Control1 is received by the first column decoder and the moment at which the second control signal Control2 is received by the second column decoder indicates higher favorability for ensuring that the first column decoder and the second column decoder perform the subsequent operations simultaneously.

Based on this, a smaller difference between the first delay of the initial control signal Control received by the first operation unit 111 and the second delay of the initial control signal Control received by the second operation unit 112, that is, a smaller preset threshold, indicates higher favorability for reducing the difference between the moment at which the first control signal Control1 is received by the first column decoder and the moment at which the second control signal Control2 is received by the second column decoder, and thus higher favorability for ensuring that the first column decoder and the second column decoder perform the subsequent operations simultaneously. In a good state, with the excellent transmission performance of the first transmission unit 105, the preset threshold can be 0 ps. As there are influences of other factors in practical application, controlling the preset threshold to be no greater than 30 ps is also beneficial to ensuring that the first column decoder and the second column decoder perform the subsequent operations almost simultaneously, so as to avoid errors in the subsequent operations.

In some embodiments, referring to FIG. 3, FIG. 3 is a schematic partial top view of a wiring structure according to an embodiment of the present disclosure. The first operation unit 111 includes a first AND gate circuit 121 and a first buffer 131 in series. The first AND gate circuit 121 receives the initial control signal Control provided by the first transmission unit 105 and the first enable signal FAR_EN provided by the signal processing unit 104, and the first AND gate circuit 121 generates the first control signal Control1 based on the initial control signal Control and the first enable signal FAR_EN, and transmits the first control signal Control1 to the first buffer 131.

It should be noted that, the first buffer 131 buffers the first control signal Control1, which is beneficial to reducing the distortion rate of the first control signal Control1, so as to improve the driving capability of the first control signal Control1, for example, improve the capability of the first control signal Control1 for driving the first column decoder.

In some embodiments, the first buffer 131 may include M pairs of inverters in series, where M is a positive integer. One pair of inverters in series include two inverters in series. It can be understood that, two inverters in series can effectively reduce the distortion rate of the first control signal Control1. Specifically, the first inverter in the two inverters in series can invert the first control signal Control1, and the second inverter can re-invert the inverted signal, to generate the first control signal Control1 that has been buffered. In this way, the influence on the duty ratio of the first control signal Control1 is avoided by inverting the first control signal Control1 twice to cancel the influence of the transition time of the rising/falling edge in the first control signal Control1, so as to reduce the distortion rate of the first control signal Control1.

In some embodiments, with continued reference to FIG. 3, the second operation unit 112 includes a second AND gate circuit 122 and a second buffer 132 in series. The second AND gate circuit 122 receives the initial control signal Control provided by the first transmission unit 105 and the second enable signal NEAR_EN provided by the signal processing unit 104, and the second AND gate circuit 122 generates the second control signal Control2 based on the initial control signal Control and the second enable signal NEAR_EN, and transmits the second control signal Control2 to the second buffer 132.

It should be noted that, the second buffer 132 buffers the second control signal Control2, which is beneficial to reducing the distortion rate of the second control signal Control2, so as to improve the driving capability of the second control signal Control2, for example, improve the capability of the second control signal Control2 for driving the second column decoder. In some embodiments, the second buffer 132 may also include M pairs of inverters in series, where M is a positive integer. One pair of inverters in series include two inverters in series. The parts of the second buffer 132 that are the same as or similar to the first buffer 131 are not described herein.

It should be noted that, FIG. 3 shows an example in which the first AND gate circuit 121 and the second AND gate circuit 122 each include only one AND gate. In practical application, specific configurations of the first AND gate circuit 121 and the second AND gate circuit 122 are not limited, and any circuit capable of implementing AND gate logic can be the first AND gate circuit 121 or the second AND gate circuit 122.

The first transmission unit 105 is described in detail below.

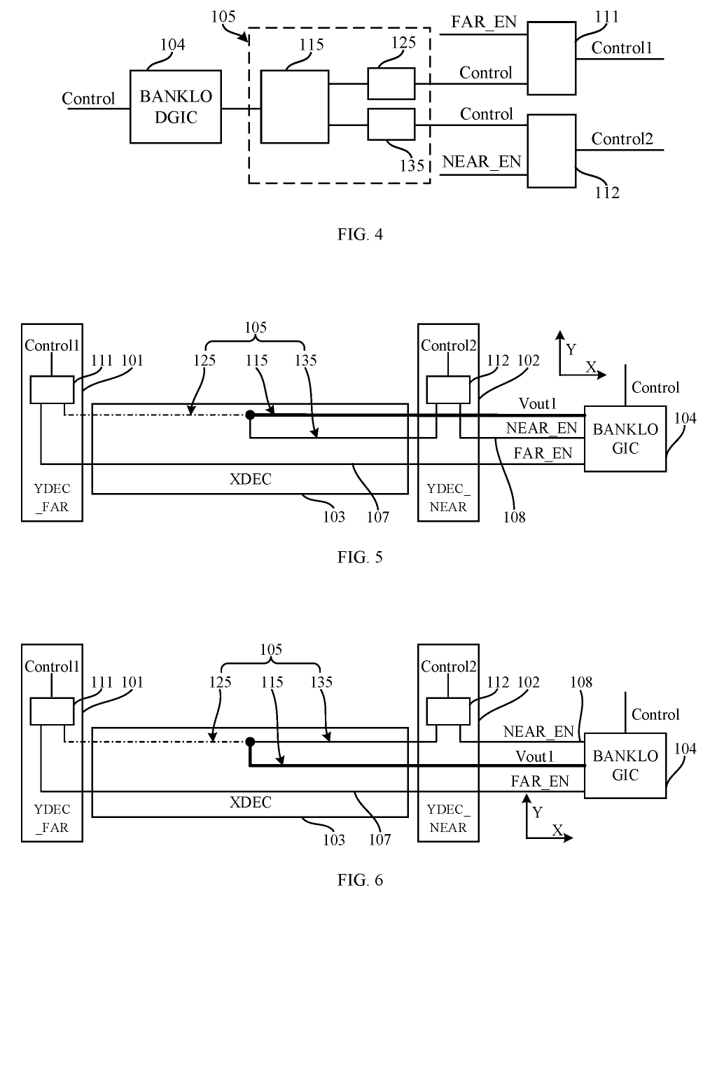

In some embodiments, referring to FIG. 4, the first transmission unit 105 includes a main path 115, a first branch 125, and a second branch 135. One end of the main path 115 is electrically connected to the signal processing unit 104, the other end of the main path 115 is electrically connected to one end of the first branch 125 and one end of the second branch 135 separately, the other end of the first branch 125 is electrically connected to the first operation unit 111, and the other end of the second branch 135 is electrically connected to the second operation unit 112. In this way, the first transmission unit 105 splits the transmission of the received signal, such that the initial control signal Control received by the signal processing unit 104 can be transmitted to the first operation unit 111 and the second operation unit 112 separately. It can be understood that, during the transmission of the signal in the first transmission unit 105, the signal on the main path 115 is transmitted to the first branch 125 and the second branch 135 separately midway, the ratio of a transmission path of the control signal on the first branch 125 to a transmission path on the second branch 135 is close to 1, such that the first branch 125 and the second branch 135 do not need to be further rerouted, as the difference between the first delay of the initial control signal Control received by the first operation unit 111 and the second delay of the initial control signal Control received by the second operation unit 112 is already ensured to be less than the preset threshold.

It should be noted that, FIG. 4 is a combined functional block diagram of a signal processing unit, a first transmission unit, a first operation unit, and a second operation unit in a wiring structure according to an embodiment of the present disclosure. To illustrate the transmission path of the initial control signal Control through the signal processing unit 104, the first transmission unit 105, the first operation unit 111, and the second operation unit 112, the first transmission unit 105 is shown in FIG. 4 merely as a simple functional block diagram, and the position relationships among the signal processing unit 104, the first transmission unit 105, the first operation unit 111, and the second operation unit 112 are not limited in FIG. 4.

In some embodiments, the main path 115 and the first branch 125 together form a first transmission path, and the main path 115 and the second branch 135 together form a second transmission path. The first transmission path is configured to transmit the initial control signal Control to the first operation unit 111, the second transmission path is configured to transmit the initial control signal Control to the second operation unit 112, and the ratio of a first length of the first transmission path to a second length of the second transmission path ranges from 0.9 to 1.1.

It should be noted that, the initial control signal Control transmitted over the first transmission path and the second transmission path is a signal that has been processed by the signal processing unit 104. As there are different internal circuit designs for the signal processing unit 104, the signal processed by the signal processing unit 104 and then transmitted over the first transmission path and the second transmission path is different, but the signal finally transmitted to the first operation unit 111 and the second operation unit 112 via the first transmission unit 105 is the initial control signal Control processed by both the signal processing unit 104 and the first transmission unit 105.

It should be noted that, any one of the main path 115, the first branch 125, and the second branch 135 may not be a transmission line extending along a fixed direction, and any one of the main path 115, the first branch 125, and the second branch 135 may be a transmission line with a bended section or a transmission line spanning at least one metal layer. Based on this, the first transmission path formed by the main path 115 and the first branch 125 may not extend along a fixed direction, and the second transmission path formed by the main path 115 and the second branch 135 may not extend along a fixed direction. Therefore, setting the ratio of the first length of the first transmission path to the second length of the second transmission path to 0.9 to 1.1 is beneficial to reducing the difference between the total length of the transmission of the signal over the first transmission path and the total length of the transmission of the signal over the second transmission path, and thus is beneficial to ensuring that the difference between the first delay of the initial control signal Control received by the first operation unit 111 and the second delay of the initial control signal Control received by the second operation unit 112 is less than the preset threshold.

It can be understood that, in a good state, the ratio of the first length to the second length is controlled to be 1, that is, the total length of the transmission of the signal over the first transmission path is the same as the total length of the transmission of the signal over the second transmission path, which is beneficial to further reducing the difference between the first delay and the second delay, so as to improve the transmission performance of the first transmission unit 105. As there are influences of the manufacturing process of the first transmission unit 105 in practical application, the ratio of the first length of the first transmission path to the second length of the second transmission path is controlled to be 0.9 to 1.1, which is beneficial to controlling the preset threshold to be no greater than 30 ps.

The specific configurations of the signal processing unit 104 and the first transmission unit 105 include at least the following two cases:

In some embodiments, referring to FIG. 5 or FIG. 6, the first transmission unit 105 may be located within the row decoding region 103.

It should be noted that, the first transmission unit 105 being located within the row decoding region 103 means that a main wire of the first transmission unit 105 is located within the row decoding region 103; to transmit a signal to the first operation unit 111, a part of wires of the first transmission unit 105 needs to cross over from the row decoding region 103 to the first column decoding region 101; to transmit a signal to the second operation unit 112, a part of wires of the first transmission unit 105 needs to cross over from the row decoding region 103 to the second column decoding region 102; and to receive the initial control signal Control processed by the signal processing unit 104, a part of wires of the first transmission unit 105 needs to cross over from the signal processing unit 104 to the row decoding region 103.

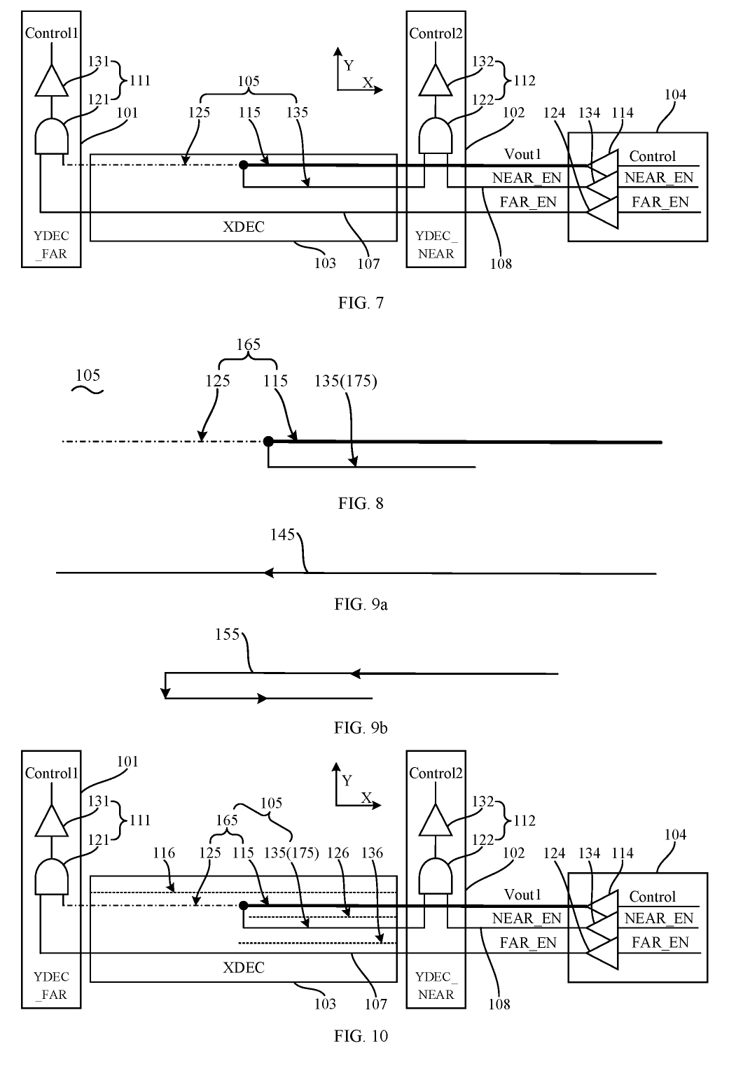

In some embodiments, referring to FIG. 5, FIG. 6, or FIG. 7, the signal processing unit 104 is configured to buffer the received initial control signal Control to obtain and output a first output signal Vout1; and the first transmission unit 105 is configured to receive and transmit the first output signal Vout1 to the first operation unit 111 and the second operation unit 112 separately.

FIG. 5 is another schematic top view of a wiring structure according to an embodiment of the present disclosure; FIG. 6 is still another schematic top view of a wiring structure according to an embodiment of the present disclosure; and FIG. 7 is yet another schematic top view of a wiring structure according to an embodiment of the present disclosure. FIG. 5, FIG. 6, and FIG. 7 will be described in detail subsequently.

In some embodiments, referring to FIG. 7, the signal processing unit 104 includes a third buffer 114, a fourth buffer 124, and a fifth buffer 134.

The third buffer 114 is configured to receive and buffer the initial control signal Control to generate a first output signal Vout1. It should be noted that, the third buffer 114 buffers the initial control signal Control, which is beneficial to reducing the distortion rate of the initial control signal Control, so as to improve the driving capability of the initial control signal Control. In some embodiments, the third buffer 114 may include M pairs of inverters in series, where M is a positive integer. One pair of inverters in series include two inverters in series. The parts of the third buffer 114 that are the same as or similar to the first buffer 131 are not described herein.

It should be noted that, the waveform of the first output signal Vout1 is the same as the waveform of the initial control signal Control, and the first output signal Vout1 is equivalent to the initial control signal Control.

The fourth buffer 124 is configured to receive and buffer the first enable signal FAR_EN, to reduce the distortion rate of the first enable signal FAR_EN output by the signal processing unit 104 and improve the driving capability of the first enable signal FAR_EN output by the signal processing unit 104; and the fifth buffer 134 is configured to receive and buffer the second enable signal NEAR_EN, to reduce the distortion rate of the second enable signal NEAR_EN output by the signal processing unit 104 and improve the driving capability of the second enable signal NEAR_EN output by the signal processing unit 104. It should be noted that, the parts of the fourth buffer 124 and the fifth buffer 134 that are the same as or similar to the first buffer 131 are not described herein.

In some embodiments, referring to FIG. 5, FIG. 6, or FIG. 7, the first transmission unit 105 includes a main path 115, a first branch 125, and a second branch 135, and the main path 115, the first branch 125, and the second branch 135 are located at the same metal layer.

It should be noted that, FIG. 5 and FIG. 6 show two different arrangements of the main path 115, the first branch 125, and the second branch 135. In FIG. 5, the second branch 135 is partially bended as the main path 115 transitions to the first branch 125 and the second branch 135, and in FIG. 6, the main path 115 is partially bended as the main path 115 transitions to the first branch 125 and the second branch 135. In practical application, specific arrangements of the main path 115, the first branch 125, and the second branch 135 are not limited, provided that the ratio of a first length of a first transmission path formed by the main path 115 and the first branch 125 to a second length of a second transmission path formed by the main path 115 and the second branch 135 is close to 1. For example, the ratio of the first length to the second length ranges from 0.9 to 1.1. In addition, a specific configuration of the signal processing unit 104 in FIG. 5 is shown in FIG. 7.

The wiring structure according to an embodiment of the present disclosure is described in detail below with reference to the first transmission unit 105 shown in FIG. 7.

In some embodiments, referring to both FIGS. 7 and 8, FIG. 8 is a schematic top view of the first transmission unit 105 in the wiring structure shown in FIG. 7. The main path 115 and the first branch 125 form a first transmission line 165 running through the row decoding region 103, and the second branch 135 is a second transmission line 175 that is partially bended.

It should be noted that, the main path 115 and the first branch 125 are at the same conductive layer in the wiring structure, and are used as the first transmission line 165, with the second branch 135 alone as the second transmission line 175. The second transmission line 175 is in contact with a non-end region of the first transmission line 165. In this way, compared with an existing wiring structure with two wires in no contact with each other and one of the wires rerouted, the first transmission unit 105 occupies fewer tracks, which is only two, in the row decoding region 103. This is beneficial to further reducing the track resources occupied in the row decoding region 103 by the first transmission unit 105, and thus is beneficial to further reducing the space for laying out the whole wiring structure.

In some embodiments, referring to FIG. 8, an unbent section of the second transmission line 175 is parallel to and spaced apart from the first transmission line 165, and a bended section of the second transmission line 175 is electrically connected to the intersection point of the main path 115 and the second transmission line 175.

In some embodiments, referring to both FIG. 8 and FIG. 9a, the main path 115 and the first branch 125 together form a first transmission path 145, and referring to both FIG. 8 and FIG. 9b, the main path 115 and the second branch 135 together form a second transmission path 155. The initial control signal Control processed by the signal processing unit 104, that is, the first output signal Vout1 (refer to FIG. 7), is transmitted to the first operation unit 111 (refer to FIG. 7) over the first transmission path 145, and is transmitted to the second operation unit 112 (refer to FIG. 7) over the second transmission path 155.

FIG. 9a is a schematic top view of the first transmission path 145 formed by the main path 115 and the first branch 125 in the first transmission unit 105 shown in FIG. 8, and FIG. 9b is a schematic top view of the second transmission path 155 formed by the main path 115 and the second branch 135 in the first transmission unit 105 shown in FIG. 8.

In some embodiments, referring to FIG. 10, the wiring structure may further include: a first shield line 116, located on a side of the first transmission line 165 far away from the second transmission line 175; a second shield line 126, located between the first transmission line 165 and the second transmission line 175; and a third shield line 136, located on a side of the second transmission line 175 far away from the first transmission line 165.

FIG. 10 is a schematic top view of a wiring structure further provided with shield lines based on the structure shown in FIG. 7. The shield lines described herein include the first shield line 116, the second shield line 126, and the third shield line 136.

It can be understood that, further providing the first shield line 116 is beneficial to reducing the electrical interference from other wires within the row decoding region 103 and at the same metal layer as the first transmission line 165 to the first transmission line 165; further providing the second shield line 126 is beneficial to reducing the electrical interference from the first transmission line 165 and the second transmission line 175 to each other; and further providing the third shield line 136 is beneficial to reducing the electrical interference from other wires within the row decoding region 103 and at the same metal layer as the second transmission line 175 to the second transmission line 175. In this way, the first shield line 116, the second shield line 126, and the third shield line 136 are provided, such that the first transmission line 165 and the second transmission line 175 are both surrounded by the shield lines, to reduce the electrical interference to the first transmission line 165 and the second transmission line 175, which is beneficial to improving the transmission accuracy of the first transmission unit 105.

It should be noted that, the combination of the first shield line 116, the second shield line 126, and the third shield line 136 is beneficial to reducing the distortion rate of the first output signal Vout1 in transmission through the first transmission line 165, and to reducing the distortion rate of the first output signal Vout1 in transmission through the second transmission line 175, such that the first transmission unit 105 has high transmission accuracy. Further, this is beneficial to improving the accuracy of the first output signal Vout1 received by the first operation unit 111, and thus to improving the probability that the first control signal Control1 generated by the first operation unit 111 based on the first output signal Vout1 is accurately identified by the first column decoder; and beneficial to improving the accuracy of the first output signal Vout1 received by the second operation unit 112, and thus to improving the probability that the second control signal Control2 generated by the second operation unit 112 based on the first output signal Vout1 is accurately identified by the second column decoder.

In addition, as the first output signal Vout1 to be shielded is transmitted only over the first transmission line 165 and the second transmission line 175, shield lines only need to be provided around the two signal transmission lines, that is, the first transmission line 165 and the second transmission line 175, to meet the requirement. Based on this, only three shield lines, that is, the first shield line 116, the second shield line 126, and the third shield line 136 need to be provided to ensure that both the first operation unit 111 and the second operation unit 112 can receive the first output signal Vout1 of high accuracy. Compared with an existing wiring structure with two wires in no contact with each other and one of the wires rerouted, fewer shield lines need to be configured for the first transmission line 165 and the second transmission line 175 that intersect at a point. This is beneficial to further reducing the track resources occupied in the row decoding region 103 by the wiring structure, and thus is beneficial to further reducing the space for laying out the whole wiring structure.

In some embodiments, the first shield line 116, the second shield line 126, and the third shield line 136 are all grounded to achieve electromagnetic shielding, so as to shield the first transmission line 165 and the second transmission line 175 from in-between electrical interference and shield the first transmission line 165 and the second transmission line 175 from electrical interference from other wires.

In some embodiments, referring to FIG. 10, the length of the first shield line 116 may be equal to the length of the row decoding region 103 along the first direction X, which is beneficial to ensuring that the whole first transmission line 165 located within the row decoding region 103 is not electrically interfered by another external wire; the length of the second shield line 126 may be slightly less than the length of the second transmission line 175 located within the row decoding region 103 along the first direction X, which is beneficial to ensuring that a majority of the second transmission line 175 directly facing the first transmission line 165 in the second direction Y is provided with the second shield line 126, so as to improve the effect of the second shield line 126 of shielding the electrical interference between the first transmission line 165 and the second transmission line 175; and the length of the third shield line 136 may be slightly greater than the length of the second transmission line 175 located within the row decoding region 103 along the first direction X, which is beneficial to ensuring that the whole first transmission line 165 located within the row decoding region 103 is not electrically interfered by another external wire, for example, the second transmission unit 107.

It should be noted that, the first shield line 116, the second shield line 126, the third shield line 136, the first transmission line 165, and the second transmission line 175 may be located at the same metal layer.

In practical application, the lengths of the first shield line 116, the second shield line 126, and the third shield line 136 in the first direction X may be adjusted based on practical requirements.

In some embodiments, referring to FIGS. 2, 3, 5 to 7 and 10, the wiring structure may further include: a second transmission unit 107, electrically connecting the signal processing unit 104 and the first operation unit 111 and configured to transmit the first enable signal FAR_EN to the first operation unit 111; and a third transmission unit 108, electrically connecting the signal processing unit 104 and the second operation unit 112 and configured to transmit the second enable signal NEAR_EN to the second operation unit 112.

In some cases, since the signal processing unit 104 is located on a side near the second column decoding region 102 and far away from the first column decoding region 101, and the first enable signal FAR_EN needs to be transmitted to the first column decoding region 101 relatively far away from the signal processing unit 104, the second transmission unit 107 for transmitting the first enable signal FAR_EN needs to run through the row decoding region 103 along the first direction X. By contrast, the third transmission unit 108 can transmit the second enable signal NEAR_EN to the second column decoding region 102 without running through the row decoding region 103.

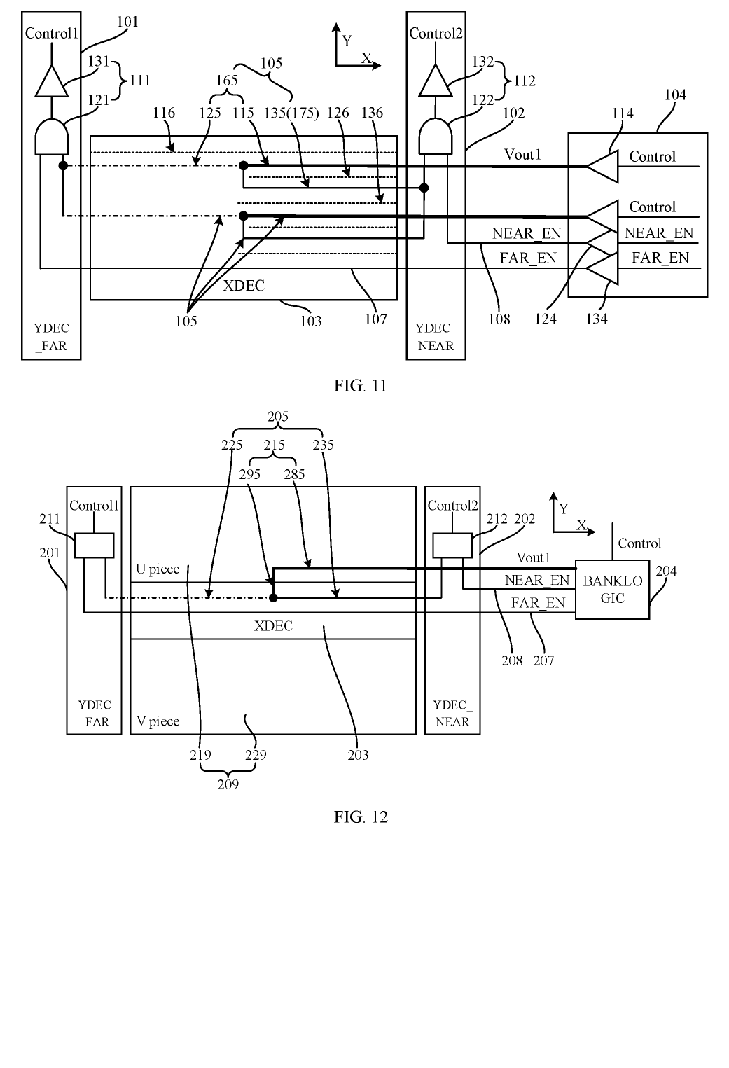

In some embodiments, referring to FIG. 11, FIG. 11 is yet another schematic top view of a wiring structure according to an embodiment of the present disclosure. The initial control signal Control includes N types of sub-control signals, the N types of sub-control signals are in the one-to-one correspondence with N first transmission units 105, the N first transmission units 105 are spaced apart along a second direction Y, the second direction Y intersects the first direction X, the N first transmission units 105 correspond to the same second transmission unit 107 and the same third transmission unit 108, and N is a positive integer.

It should be noted that, different sub-control signals are not in an active state simultaneously, and therefore different sub-control signals can be first processed by the signal processing unit 104 and the first transmission unit 105 and then transmitted to the same first operation unit 111 and the same second operation unit 112. Further, different sub-control signals received by the first operation unit 111 may share the same first enable signal FAR_EN, and different sub-control signals received by the second operation unit 112 may share the same second enable signal NEAR_EN. In addition, each of the sub-control signals is in the one-to-one correspondence with the third buffer 114 in the signal processing unit 104.

It can be understood that, the signal processing unit 104 only primarily processes, that is, buffers, the received initial control signal Control. The logical operation processing for the initial control signal Control and the first enable signal FAR_EN is provided on the first operation unit 111 in the first column decoding region 101, and the logical operation processing for the initial control signal Control and the second enable signal NEAR_EN is provided on the second operation unit 112 in the second column decoding region 102. Based on this, when transmission paths for the N types of sub-control signals need to be provided in the wiring structure, only N first transmission units 105 in the one-to-one correspondence with the N types of sub-control signals need to be provided, and there are one second transmission unit 107 and one third transmission unit 108 all along. In this way, in one aspect, a single first transmission unit 105 occupies only two tracks in the row decoding region 103, and N first transmission units 105 occupy only 2N tracks in the row decoding region 103; in another aspect, only one track needs to be provided in the row decoding region 103 for the second transmission unit 107 to use. In other words, the quantity of tracks occupied in the row decoding region 103 by a single first transmission unit 105 can be reduced, and the quantity of second transmission units 107 can be reduced, to further reduce the total quantity of wires in the wiring structure, such that the track resources occupied in the row decoding region 103 by the wiring structure can be further reduced, which is beneficial to further reducing the space for laying out the whole wiring structure. It should be noted that, the wires in the wiring structure include the first transmission line 165, the second transmission line 175, and the second transmission unit 107.

It should be noted that, only two first transmission units 105 spaced apart along the second direction Y are shown in FIG. 11, but in practical application, the quantity of first transmission units 105 equal to the quantity of sub-control signals may be designed based on the quantity of sub-control signals. For example, the quantity of first transmission units 105 spaced apart along the second direction Y is designed to be three, four, or five.

In some embodiments, the N types of sub-control signals included in the initial control signal Control may be a write enable signal WrEn, a read enable signal RdEn, a read enable complement signal RdEnN, or the like.

In some embodiments, referring to FIG. 11, the first transmission unit 105, the first shield line 116, and the second shield line 126 are in the one-to-one correspondence, and one first shield line 116 is provided between two adjacent first transmission units 105 along the second direction Y. In other words, only two shield lines, that is, the first shield line 116 and the second shield line 126, need to be repeatedly arranged for different transmitted sub-control signals, and two adjacent first transmission units 105 along the second direction Y may share one first shield line 116, which is beneficial to reducing the quantity of first shield lines 116 to be provided, and to further reducing the track resources occupied in the row decoding region 103 by the whole wiring structure.

In some embodiments, with continued reference to FIG. 11, one third shield line 136 is provided between one first transmission unit 105 closest to the second transmission unit 107 and the second transmission unit 107 along the second direction Y. It can be understood that, regardless of the quantity of first transmission units 105 spaced apart along the second direction Y, the units share one second transmission unit 107. That is, only one third shield line 136 needs to be provided, which is beneficial to reducing the track resources occupied in the row decoding region 103 by the whole wiring structure by reducing the quantity of second transmission units 107 to be provided.

It can be understood that, to transmit the N types of sub-control signals and avoid the distortion of the N types of sub-control signals in transmission to the first operation unit 111 and the second operation unit 112, employing the design of the first transmission unit 105, the design of the first operation unit 111 in the first column decoding region 101, and the design of the second operation unit 112 in the second column decoding region 102 that are shown in FIG. 11 is beneficial to reducing the total quantity of wires required to be provided in the row decoding region 103 to (4N+1+1), so as to further reduce the track resources occupied in the row decoding region 103 by the whole wiring structure.

It should be noted that, among the (4N+1+1) wires, "4" refers to the first transmission line 165, the second transmission line 175, the first shield line 116, and the second shield line 126 respectively, one "1" refers to the third shield line 136, and the other "1" refers to the second transmission unit 107.

It should be noted that, to distinguish between the main path 115, the first branch 125, and the second branch 135, throughout FIGS. 5 to 8, FIGS. 10 and 11, the main path 115 is indicated by a thicker solid line, the first branch 125 is indicated by a dot-dash line, and the second branch 135 is indicated by a thinner solid line. In addition, to distinguish between the main path 115, the first branch 125, the second branch 135, and the shield lines, throughout FIGS. 10 and 11, the shield lines are indicated by broken lines. The shield lines described herein include the first shield line 116, the second shield line 126, and the third shield line 136. Further, to distinguish between the first shield line 116, the second shield line 126, and the third shield line 136, throughout FIGS. 10 and 11, the first shield line 116 is indicated by a broken line with the largest length in the first direction X, the second shield line 126 is indicated by a broken line with the smallest length in the first direction X, and the third shield line 136 is indicated by a broken line with the middle length in the first direction X.

In the embodiments shown in FIGS. 5 to 11, an example in which the first transmission unit 105 is located within the row decoding region 103 is used. In other embodiments, only some wires in the first transmission unit may be designed to be within the row decoding region, and other wires may be designed to be within a memory array region.

Embodiments in which the first transmission unit is partially located within the row decoding region and partially located within the memory array region are described in detail below with reference to the drawings. It should be noted that, content that is the same as or that corresponds to the content of the foregoing embodiments is not described herein again.

In other embodiments, referring to FIG. 12, FIG. 12 is yet another schematic top view of a wiring structure according to an embodiment of the present disclosure. The wiring structure includes a first column decoding region 201, a second column decoding region 202, a row decoding region 203, a signal processing unit 204, and a first transmission unit 205. The first column decoding region 201 is provided with a first operation unit 211, and the second column decoding region 202 is provided with a second operation unit 212. The first transmission unit 205 includes a main path 215, a first branch 225, and a second branch 235. Based on this, the wiring structure may further include a memory array region 209. The memory array region 209 is adjacent to the row decoding region 203 along a second direction Y, and is located between the first column decoding region 201 and the second column decoding region 202.

In some cases, with continued reference to FIG. 12, the memory array region 209 may include a first memory array region 219 and a second memory array region 229, and the row decoding region 203 is located between the first memory array region 219 and the second memory array region 229. It should be noted that, in FIG. 12, the first memory array region 219 is indicated by "U piece", and the second memory array region 229 is indicated by "V piece".

With continued reference to FIG. 12, the main path 215 may include a first main path 285 located within the memory array region 209 and a second main path 295 extending from the memory array region 209 to the row decoding region 203, the first main path 285 is electrically connected to the signal processing unit 204, and the second main path 295 is electrically connected to the first branch 225 and the second branch 235 separately.

It can be understood that, the main part of the main path 215, that is, the first main path 285, is not located within the row decoding region 203, such that the main path 215 does not occupy too many tracks in the row decoding region 203, which is beneficial to reducing the track resources occupied in the row decoding region 203 by the wiring structure.

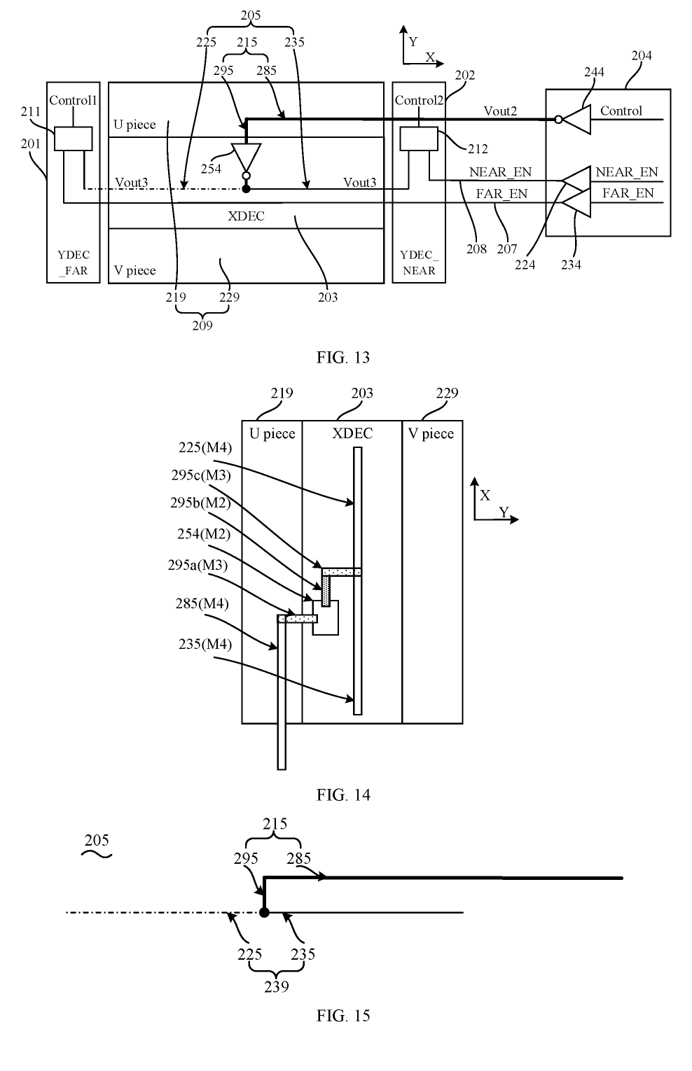

In some embodiments, referring to FIG. 13, FIG. 13 is yet another schematic top view of a wiring structure according to an embodiment of the present disclosure. The signal processing unit 204 includes a first inverter 244 configured to receive and invert the initial control signal Control to obtain and output a second output signal Vout2. It can be understood that, unlike the previous embodiments, a component of the signal processing unit 204 for receiving and processing the initial control signal Control is not the third buffer, but an odd-numbered quantity of first inverters 244. Therefore, the waveform of the second output signal Vout2 is opposite to the waveform of the initial control signal Control.

It should be noted that, the signal processing unit 204 further includes a fourth buffer 224 and a fifth buffer 234. The fourth buffer 224 and the fifth buffer 234 are similar to the fourth buffer and the fifth buffer in the foregoing embodiments, and are not described herein again. In addition, the first operation unit 211 and the second operation unit 212 are also similar to the first operation unit and the second operation unit in the foregoing embodiments, and are not described herein again.

With continued reference to FIG. 13, the first main path 285 is configured to receive and transmit the second output signal Vout2 to the second main path 295; the second main path 295 is provided with a second inverter 254 configured to receive and invert the second output signal Vout2 to obtain and output a third output signal Vout3; the first branch 225 is configured to receive and transmit the third output signal Vout3 to the first operation unit 211; and the second branch 235 is configured to receive and transmit the third output signal Vout3 to the second operation unit 212.

It should be noted that, the waveform of the third output signal Vout3 may be the same as the waveform of the initial control signal Control, and in this case, the third output signal Vout3 is equivalent to the initial control signal Control, which is beneficial to ensuring that both the first operation unit 211 and the second operation unit 212 receive the initial control signal Control.

Further, since the first main path 285 is not located within the row decoding region 203 and needs the second main path 295 to extend from the memory array region 209 to the row decoding region 203, the signal needs to be transmitted from the memory array region 209 to the row decoding region 203 during the transmission over the main path 215, and therefore a transmission path of the signal over the main path 215 is long. Based on this, the first inverter 244 is provided in the signal processing unit 204 to primarily invert the initial control signal Control, and the second inverter 254 is further provided on the main path 215 to re-invert the initial control signal Control, such that the interference to the second output signal Vout2 during transmission does not further affect the third output signal Vout3 after the second inverter 254 inverts the second output signal Vout2. In other words, the influences on the second output signal Vout2 and the third output signal Vout3 during transmission do not affect each other. In this way, during the transmission of the initial control signal Control from the signal processing unit 204 to the first operation unit 211 and the second operation unit 212 separately, the interference to the signal on the main path 215 and the interference to the signal on the first branch 225 do not accumulate, and the interference to the signal on the main path 215 and the interference to the signal on the second branch 235 do not accumulate, which is beneficial to improving the accuracy of the transmission of the initial control signal Control by the signal processing unit 204 and the first transmission unit 205, that is, improving the transmission performance of the wiring structure.

In some cases, referring to both FIGS. 13 and 14, FIG. 14 is a schematic combined top view of a first transmission unit, a first memory array region, a row decoding region, and a second memory array region in the wiring structure shown in FIG. 13. The first main path 285 is located at a metal layer M4, the second inverter 254 is designed to be at a metal layer M2 within the row decoding region 203 due to a limited layout space in the row decoding region 203, and the first branch 225 and the second branch 235 are designed to be at the metal layer M4 within the row decoding region 203, to fully utilize the layout space in the row decoding region 203.

Based on this, the second main path 295 is designed to include a first portion 295a, a second portion 295b, a third portion 295c, and a first conductive pillar (not shown in the figure) with two ends in contact with the first main path 285 and the first portion 295a respectively, a second conductive pillar (not shown in the figure) with two ends in contact with the first portion 295a and the second inverter 254 respectively, a third conductive pillar (not shown in the figure) with two ends in contact with the second inverter 254 and the second portion 295b respectively, a fourth conductive pillar (not shown in the figure) with two ends in contact with the second portion 295b and the third portion 295c respectively, and a fifth conductive pillar (not shown in the figure) with two ends in contact with the third portion 295c and the first branch 225 respectively.

The first portion 295a is located at a metal layer M3, and in one aspect, the second output signal Vout2 on the first main path 285 at the metal layer M4 is transmitted from the metal layer M4 to the metal layer M3 via the first conductive pillar, and in another aspect, the second output signal Vout2 on the first portion 295a at the metal layer M3 is transmitted from the metal layer M3 to the metal layer M2 via the second conductive pillar, for the transmission to the second inverter 254; the second portion 295b is located at the metal layer M2, and in one aspect, the third output signal Vout3 output by the second inverter 254 at the metal layer M2 is transmitted to the second portion 295b via the third conductive pillar, and in another aspect, the third output signal Vout3 on the second portion 295b at the metal layer M2 is transmitted from the metal layer M2 to the metal layer M3 via the fourth conductive pillar, for the transmission to the third portion 295c; and the third portion 295c is located at the metal layer M3, and the third output signal Vout3 on the third portion 295c at the metal layer M3 is transmitted from the metal layer M3 to the metal layer M4 via the fifth conductive pillar, for the transmission to the first branch 225 and the second branch 235 separately.

It should be noted that, since other important electrical components are further provided in a middle region of the row decoding region 203 along the first direction X, the second inverter 254 is provided at the metal layer M2 in the row decoding region 203, and the second inverter 254 is located in a region near the middle region of the row decoding region 203. Based on this, to ensure that the ratio of the first length of the first transmission path to the second length of the second transmission path is close to 1, the third portion 295c is designed to be within the middle region of the row decoding region 203 along the first direction X, which is beneficial to further ensuring consistent transmission paths through the first branch 225 and the second branch 235 for the signals.

It should be noted that, to clearly illustrate the position relationships among the first main path 285, the second main path 295, the first branch 225, and the second branch 235, FIG. 14 shows a perspective drawing for the first main path 285, the first branch 225, and the second branch 235, and the same drawing manner is used for the structures at the same metal layer. The metal layer at which each of the structures is located is separately marked.

In some embodiments, referring to FIG. 15, FIG. 15 is a schematic top view of the first transmission unit in the wiring structure shown in FIG. 12. The first branch 225 and the second branch 235 are located at the same metal layer, and the first branch 225 and the second branch 235 form a third transmission line 239 running through the row decoding region 203 (refer to FIG. 12).

It should be noted that, the first branch 225 and the second branch 235 are at the same conductive layer in the wiring structure, and are used as the third transmission line 239. In this way, compared with an existing wiring structure with two wires in no contact with each other and one of the wires rerouted, one third transmission line 239 in the first transmission unit 205 is located within the row decoding region 203, and a majority of the main path 215 is located within the memory array region 209. This is beneficial to further reducing the quantity of tracks occupied in the row decoding region 203 by the wiring structure, that is, one third transmission line 239 is occupied, and to further reducing the track resources occupied in the row decoding region 203 by the first transmission unit 205, and thus is beneficial to further reducing the space for laying out the whole wiring structure.

In some embodiments, the first main path 285 of the main path 215 may also be located at the same metal layer as the first branch 225 and the second branch 235, but the first main path 285 is located within the memory array region 209.

In some embodiments, referring to FIG. 15, the first main path 285 is parallel to and spaced apart from the third transmission line 239.

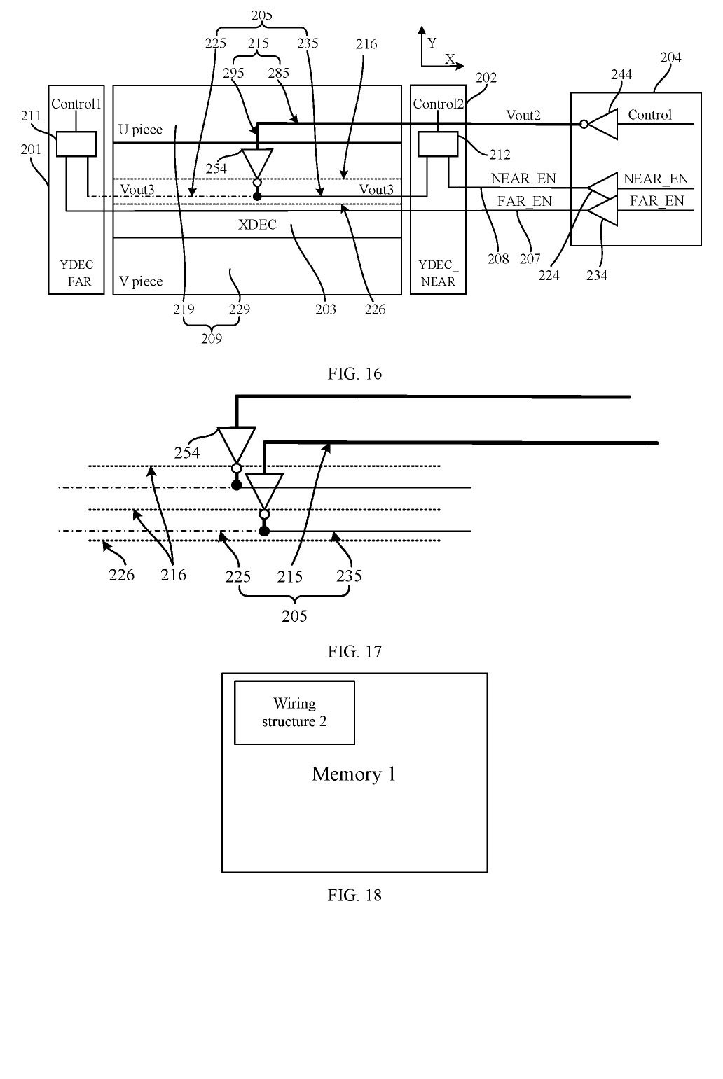

In some embodiments, referring to FIG. 16, FIG. 16 is a schematic top view of a wiring structure further provided with shield lines based on the structure shown in FIG. 13, and the wiring structure may further include: a fourth shield line 216 and a fifth shield line 226 that are separately located on two opposite sides of the third transmission line 239 (refer to FIG. 15) along the second direction Y.

FIG. 16 is a schematic top view of a wiring structure further provided with shield lines based on the wiring structure shown in FIG. 13. The shield lines described herein include the fourth shield line 216 and the fifth shield line 226.

It can be understood that, further providing the fourth shield line 216 and the fifth shield line 226 is beneficial to reducing the electrical interference from other wires located within the row decoding region 203 and at the same metal layer as the third transmission line 239 to the third transmission line 239. In other words, the fourth shield line 216 and the fifth shield line 226 are provided, such that a majority of the third transmission line 239 is surrounded by the shield lines, to reduce the electrical interference to the third transmission line 239, which is beneficial to improving the transmission accuracy of the first transmission unit 205.

It should be noted that, the combination of the fourth shield line 216 and the fifth 226 is beneficial to reducing the distortion rate of the third output signal Vout3 in transmission through the third transmission line 239, such that the first transmission unit 205 has high transmission accuracy. Further, this is beneficial to improving the accuracy of the third output signal Vout3 received by the first operation unit 211, and thus to improving the probability that the first control signal Control1 generated by the first operation unit 211 based on the third output signal Vout3 is accurately identified by the first column decoder; and beneficial to improving the accuracy of the third output signal Vout3 received by the second operation unit 212, and thus to improving the probability that the second control signal Control2 generated by the second operation unit 212 based on the third output signal Vout3 is accurately identified by the second column decoder.

In addition, as the third output signal Vout3 to be shielded is transmitted only over the third transmission line 239, shield lines only need to be provided around the one signal transmission line, that is, the third transmission line 239, to meet the requirement. Based on this, only two shield lines, that is, the fourth shield line 216 and the fifth shield line 226 need to be provided to ensure that both the first operation unit 211 and the second operation unit 212 can receive the third output signal Vout3 of high accuracy. Compared with an existing wiring structure with two wires in no contact with each other and one of the wires rerouted, fewer shield lines need to be configured for the third transmission line 239. This is beneficial to further reducing the track resources occupied in the row decoding region 203 by the wiring structure, and thus is beneficial to further reducing the space for laying out the whole wiring structure.

In some embodiments, the fourth shield line 216 and the fifth shield line 226 are both grounded to achieve electromagnetic shielding, so as to shield the third transmission line 239 from electrical interference from other wires.

In some embodiments, referring to FIG. 16, the length of the fourth shield line 216 and the length of the fifth shield line 226 along the first direction X may both be equal to the length of the row decoding region 203, which is beneficial to ensuring that the whole third transmission line 239 within the row decoding region 203 is not electrically interfered by another external wire.

It should be noted that, the fourth shield line 216, the fifth shield line 226, and the third transmission line 239 may be located at the same metal layer.

In practical application, the lengths of the fourth shield line 216 and the fifth shield line 226 in the first direction X may be adjusted based on practical requirements.

In some embodiments, referring to FIGS. 12, 13, and 16, the wiring structure may further include: a second transmission unit 207, electrically connecting the signal processing unit 204 and the first operation unit 211 and configured to transmit the first enable signal FAR_EN to the first operation unit 211; and a third transmission unit 208, electrically connecting the signal processing unit 204 and the second operation unit 212 and configured to transmit the second enable signal NEAR_EN to the second operation unit 212.

It should be noted that, the second transmission unit 207 and the third transmission unit 208 are similar to the second transmission unit and the third transmission unit in the foregoing embodiments, and are not described herein again.

In some embodiments, referring to both FIGS. 16 and 17, FIG. 17 is another schematic top view of a first transmission unit in a wiring structure according to an embodiment of the present disclosure. The initial control signal Control includes N types of sub-control signals, the N types of sub-control signals are in the one-to-one correspondence with N first transmission units 205, N third transmission lines 239 in the N first transmission units 205 are spaced apart along the second direction Y, the N first transmission units 205 correspond to the same second transmission unit 207 and the same third transmission unit 208, and N is a positive integer.

It should be noted that, different sub-control signals are not in an active state simultaneously, and therefore different sub-control signals can be first processed by the signal processing unit 204 and the first transmission unit 205 and then transmitted to the same first operation unit 211 and the same second operation unit 212. Further, different sub-control signals received by the first operation unit 211 may share the same first enable signal FAR_EN, and different sub-control signals received by the second operation unit 212 may share the same second enable signal NEAR_EN. In addition, each of the sub-control signals is in the one-to-one correspondence with the first inverter 244 in the signal processing unit 204.

It can be understood that, the signal processing unit 204 primarily inverts the received initial control signal Control, and the first transmission unit 205 re-inverts the second output signal Vout2 output by the signal processing unit 204, to output the third output signal Vout3 with the same waveform as the initial control signal Control. The third output signal Vout3 is equivalent to the initial control signal Control. In addition, the logical operation processing for the initial control signal Control and the first enable signal FAR_EN is provided on the first operation unit 211 in the first column decoding region 201, and the logical operation processing for the initial control signal Control and the second enable signal NEAR_EN is provided on the second operation unit 212 in the second column decoding region 202. Based on this, when transmission paths for the N types of sub-control signals need to be provided in the wiring structure, only N first transmission units 205 in the one-to-one correspondence with the N types of sub-control signals need to be provided, and there are one second transmission unit 207 and one third transmission unit 208 all along. In this way, in one aspect, a single first transmission unit 205 occupies only one track in the row decoding region 103, and N first transmission units 205 occupy only N tracks in the row decoding region 203; in another aspect, only one track needs to be provided in the row decoding region 203 for the second transmission unit 207 to use. In other words, the quantity of tracks occupied in the row decoding region 203 by a single first transmission unit 205 can be reduced, and the quantity of second transmission units 207 can be reduced, to further reduce the total quantity of wires in the wiring structure, such that the track resources occupied in the row decoding region 203 by the wiring structure can be further reduced, which is beneficial to further reducing the space for laying out the whole wiring structure. It should be noted that, the wires in the wiring structure include the third transmission line 239 and the second transmission unit 207.

It should be noted that, only two first transmission units 205 spaced apart along the second direction Y are shown in FIG. 17, but in practical application, the quantity of first transmission units 205 equal to the quantity of sub-control signals may be designed based on the quantity of sub-control signals. For example, the quantity of first transmission units 205 spaced apart along the second direction Y is designed to be three, four, or five.

In some embodiments, referring to both FIG. 16 and FIG. 17, the fourth shield line 216 and the third transmission line 239 are in the one-to-one correspondence, and one fourth shield line 216 is provided between two adjacent third transmission units 239 along the second direction Y. In other words, only one shield line, that is, the fourth shield line 216, needs to be repeatedly arranged for different transmitted sub-control signals, and two adjacent first transmission units 205 along the second direction Y may share one fourth shield line 216, which is beneficial to reducing the quantity of fourth shield lines 216 to be provided, and to further reducing the track resources occupied in the row decoding region 203 by the whole wiring structure.

In some embodiments, one fifth shield line 226 is provided between one third transmission line 239 closest to the second transmission unit 207 and the second transmission unit 207 along the second direction Y. It can be understood that, regardless of the quantity of first transmission units 205 spaced apart along the second direction Y, the units share one second transmission unit 207. That is, only one fifth shield line 226 needs to be provided, which is beneficial to reducing the track resources occupied in the row decoding region 203 by the whole wiring structure by reducing the quantity of second transmission units 207 to be provided.

It can be understood that, to transmit the N types of sub-control signals and avoid the distortion of the N types of sub-control signals in transmission to the first operation unit 211 and the second operation unit 212, employing the design of the first transmission unit 205, the design of the first operation unit 211 in the first column decoding region 201, and the design of the second operation unit 212 in the second column decoding region 202 that are shown in FIG. 16 is beneficial to reducing the total quantity of wires required to be provided in the row decoding region 203 to (2N+1+1), so as to further reduce the track resources occupied in the row decoding region 203 by the whole wiring structure.

It should be noted that, among the (2N+1+1) wires, "2" refers to the third transmission line 239 and the fourth shield line 216 respectively, one "1" refers to the fifth shield line 226, and the other "1" refers to the second transmission unit 207.

It should be noted that, for ease of description and clear illustration of the wiring structure, FIGS. 2 to 17 are all schematic partial structural diagrams of the wiring structure.

In summary, with the denotations in FIG. 2, the signal processing unit 104 and the first transmission unit 105 work jointly to transmit the initial control signal Control received by the signal processing unit 104 to the first operation unit 111 and the second operation unit 112 separately. During the transmission, the new first transmission unit 105 is designed, and the first transmission unit 105 can be used to ensure that the difference between the first delay of the initial control signal Control received by the first operation unit 111 and the second delay of the initial control signal Control received by the second operation unit 112 is less than the preset threshold, which is beneficial to improving the transmission performance of the wiring structure. In another aspect, in the newly designed wiring structure, rather than only relying on the signal processing unit 104 to process the initial control signal Control to generate the control signals for driving the subsequent operations to be performed in the first column decoding region 101 and the second column decoding region 102, the first control signal Control1 for driving the subsequent operations to be performed in the first column decoding region 101 is generated in the first column decoding region 101, and the second control signal Control2 for driving the subsequent operations to be performed in the second column decoding region 102 is generated in the second column decoding region 102. Therefore, the first transmission unit 105 only needs to transmit one type of signals, that is, the first transmission unit 105 transmits the initial control signal Control that has been received and processed by the signal processing unit 104 to the first operation unit 111 and the second operation unit 112, to help reduce the space for laying out the first transmission unit 105, and then reduce the space for laying out the wiring structure. Further, this is beneficial to simplifying the logic of processing the initial control signal Control by the signal processing unit 104, and thus to reducing the complexity of the logic circuit in the signal processing unit 104, so as to reduce the space for laying out the signal processing unit 104 and further reduce the space for laying out the wiring structure.

FIG. 18 is a schematic structural diagram of a memory according to an embodiment of the present disclosure. Referring to FIG. 18, another embodiment of the present disclosure further provides a memory 1, including a wiring structure 2 as provided in an embodiment of the present disclosure. This is beneficial to improving the transmission performance of the wiring structure, so as to improve the electrical performance of the memory.

In some embodiments, the memory may be a DDR memory, for example, a DDR4 memory, a DDR5 memory, a DDR6 memory, an LPDDR4 memory, an LPDDR5 memory, or an LPDDR6 memory.

Those of ordinary skill in the art can understand that the foregoing implementations are specific embodiments of the present disclosure, and in practical application, various changes may be made in form and detail without departing from the spirit and scope of the embodiments of the present disclosure. Any person skilled in the art can make various changes and modifications without departing from the spirit and scope of the embodiments of the present disclosure, and the protection scope of the embodiments of the present disclosure is defined by the appended claims.

What is claimed is:

1. A wiring structure of a memory, comprising:
a first column decoding region and a second column decoding region that are spaced apart along a first direction, wherein the first column decoding region is provided with a first operation unit configured to receive an initial control signal and a first enable signal and generate a first control signal; and the second column decoding region is provided with a second operation unit configured to receive the initial control signal and a second enable signal and generate a second control signal;
a row decoding region, located between the first column decoding region and the second column decoding region;
a signal processing unit, located on a side that is near the second column decoding region and far away from the first column decoding region and configured to: receive the initial control signal, the first enable signal, and the second enable signal, and process the initial control signal, the first enable signal, and the second enable signal separately; and
a first transmission unit, wherein the first transmission unit and the signal processing unit are jointly configured to: transmit the initial control signal to the first operation unit and the second operation unit separately, and ensure that a difference between a first delay of the initial control signal received by the first operation unit and a second delay of the initial control signal received by the second operation unit is less than a preset threshold.

2. The wiring structure according to claim 1, wherein the first transmission unit comprises a main path, a first branch, and a second branch, and wherein
one end of the main path is electrically connected to the signal processing unit, the other end of the main path is electrically connected to one end of the first branch and one end of the second branch separately, the other end of the first branch is electrically connected to the first operation unit, and the other end of the second branch is electrically connected to the second operation unit.

3. The wiring structure according to claim 2, wherein the main path and the first branch together form a first transmission path, and the main path and the second branch together form a second transmission path; and
the first transmission path is configured to transmit the initial control signal to the first operation unit, the second transmission path is configured to transmit the initial control signal to the second operation unit, and a ratio of a first length of the first transmission path to a second length of the second transmission path ranges from 0.9 to 1.1.

4. The wiring structure according to claim 2, wherein the first transmission unit is located within the row decoding region.

5. The wiring structure according to claim 3, wherein the signal processing unit is configured to receive and buffer the initial control signal to obtain and output a first output signal; and
the first transmission unit is configured to receive and transmit the first output signal to the first operation unit and the second operation unit separately.

6. The wiring structure according to claim 4, wherein the main path, the first branch, and the second branch are located at a same metal layer, and the main path and the first branch form a first transmission line running through the row decoding region, and the second branch is a second transmission line that is partially bended; and
the wiring structure further comprises:
a first shield line, located on a side of the first transmission line far away from the second transmission line;
a second shield line, located between the first transmission line and the second transmission line; and
a third shield line, located on a side of the second transmission line far away from the first transmission line.

7. The wiring structure according to claim 6, further comprising:
a second transmission unit, electrically connecting the signal processing unit and the first operation unit and configured to transmit the first enable signal to the first operation unit; and
a third transmission unit, electrically connecting the signal processing unit and the second operation unit and configured to transmit the second enable signal to the second operation unit, wherein
the initial control signal comprises N types of sub-control signals, the N types of sub-control signals are in a one-to-one correspondence with N first transmission units, the N first transmission units are spaced apart along a second direction, the second direction intersects the first direction, the N first transmission units correspond to the same second transmission unit and the same third transmission unit, and N is a positive integer.

8. The wiring structure according to claim 7, wherein the first transmission unit, the first shield line, and the second shield line are in a one-to-one correspondence, and one first shield line is provided between two adjacent first transmission units along the second direction.

9. The wiring structure according to claim 7, wherein one third shield line is provided between one first transmission unit closest to the second transmission unit and the second transmission unit along the second direction.

10. The wiring structure according to claim 2, further comprising: a memory array region, wherein the memory array region is adjacent to the row decoding region along a second direction and located between the first column decoding region (201) and the second column decoding region, and the second direction intersects the first direction; and
the main path comprises a first main path located within the memory array region and a second main path extending from the memory array region to the row decoding region, the first main path is electrically connected to the signal processing unit, and the second main path is electrically connected to the first branch and the second branch separately.

11. The wiring structure according to claim 10, wherein the signal processing unit comprises a first inverter configured to receive and invert the initial control signal to obtain and output a second output signal;
the first main path is configured to receive and transmit the second output signal to the second main path;
the second main path is provided with a second inverter configured to receive and invert the second output signal to obtain and output a third output signal;
the first branch is configured to receive and transmit the third output signal to the first operation unit; and
the second branch is configured to receive and transmit the third output signal to the second operation unit.

12. The wiring structure according to claim 10, wherein the first branch and the second branch are located at a same metal layer, and the first branch and the second branch form a third transmission line running through the row decoding region; and
the wiring structure further comprises:
a fourth shield line and a fifth shield line that are separately located on two opposite sides of the third transmission line along the second direction.

13. The wiring structure according to claim 12, further comprising:
a second transmission unit, electrically connecting the signal processing unit and the first operation unit and configured to transmit the first enable signal to the first operation unit; and
a third transmission unit, electrically connecting the signal processing unit and the second operation unit and configured to transmit the second enable signal to the second operation unit, wherein
the initial control signal comprises N types of sub-control signals, the N types of sub-control signals are in a one-to-one correspondence with N first transmission units, N third transmission lines in the N first transmission units are spaced apart along the second direction, the N first transmission units correspond to the same second transmission unit and the same third transmission unit, and N is a positive integer.

14. The wiring structure according to claim 13, wherein the fourth shield line and the third transmission line are in a one-to-one correspondence, and one fourth shield line is provided between two adjacent third transmission lines along the second direction.

15. The wiring structure according to claim 13, wherein one fifth shield line is provided between one third transmission line closest to the second transmission unit and the second transmission unit along the second direction.

16. A memory, comprising a wiring structure, the wiring structure comprising:
a first column decoding region and a second column decoding region that are spaced apart along a first direction, wherein the first column decoding region is provided with a first operation unit configured to receive an initial control signal and a first enable signal and generate a first control signal; and the second column decoding region is provided with a second operation unit configured to receive the initial control signal and a second enable signal and generate a second control signal;
a row decoding region, located between the first column decoding region and the second column decoding region;
a signal processing unit, located on a side that is near the second column decoding region and far away from the first column decoding region and configured to: receive the initial control signal, the first enable signal, and the second enable signal, and process the initial control signal, the first enable signal, and the second enable signal separately; and
a first transmission unit, wherein the first transmission unit and the signal processing unit are jointly configured to: transmit the initial control signal to the first operation unit and the second operation unit separately, and ensure that a difference between a first delay of the initial control signal received by the first operation unit and a second delay of the initial control signal received by the second operation unit is less than a preset threshold.
